(19) United States
(12) Patent Application Publication
(10) Pub. No.: US 2026/0107729 A1
(43) Pub. Date: Apr. 16, 2026

(54) SUBSTRATE PROCESSING APPARATUS AND CLEANING METHOD OF LOCK KEY

(71) Applicant: Tokyo Electron Limited, Tokyo (JP)

(72) Inventor: Shota UMEZAKI, Koshi City (JP)

(21) Appl. No.: 19/358,570

(22) Filed: Oct. 15, 2025

(30) Foreign Application Priority Data
Oct. 16, 2024 (JP) 2024-181221

(51) Int. Cl. H01L 21/67; A46B 5/00; A46B 15/00

(52) U.S. Cl. CPC H10P 72/0408; A46B 5/0012; A46B 15/002; A46B 15/0051; A46B 15/0053; A46B 2200/3073

(57) ABSTRACT

A substrate processing apparatus configured to dry a substrate by replacing a liquid film formed on a top surface of the substrate with a supercritical fluid includes a pressure vessel having therein a drying chamber in which the substrate is dried; a cover body configured to close an opening of the drying chamber; a lock key configured to restrict the cover body from moving from a closing position where the cover body closes the opening toward an opening position where the cover body opens the opening; and a cleaning device configured to clean the lock key.

### CROSS-REFERENCE TO RELATED APPLICATION

This application claims the benefit of Japanese Patent Application No 2024-181221 filed on October 16 2024 the entire disclosures of which are incorporated herein by reference

### TECHNICAL FIELD

The various aspects and embodiments described herein pertain generally to a substrate processing apparatus and a cleaning method of a lock key.

### BACKGROUND

In the manufacture of semiconductor devices, to prevent pattern collapse, there is performed a supercritical drying processing in which a substrate a surface of which is covered with a liquid such as isopropyl alcohol (IPA) is dried by replacing the liquid with a supercritical fluid such as supercritical CO₂ in a supercritical vessel. To prevent a leak of the supercritical fluid of a high pressure when it is supplied into the supercritical vessel, (see, for example, Patent Document 1), a lock key is used to lock a cover body closing the supercritical vessel so that the cover body does not open.

Patent Document 1: Japanese Patent Laid-open Publication No. 2022-030850

### SUMMARY

In an exemplary embodiment, a substrate processing apparatus configured to dry a substrate by replacing a liquid film formed on a top surface of the substrate with a supercritical fluid includes a pressure vessel having therein a drying chamber in which the substrate is dried; a cover body configured to close an opening of the drying chamber; a lock key configured to restrict the cover body from moving from a closing position where the cover body closes the opening toward an opening position where the cover body opens the opening; and a cleaning device configured to clean the lock key.

### BRIEF DESCRIPTION OF THE DRAWINGS

FIG. 1 is a schematic transversal cross sectional view of a substrate processing apparatus according to an exemplary embodiment;

FIG. 2 is a schematic longitudinal cross sectional view of the substrate processing apparatus shown in FIG. 1;

FIG. 3 is another schematic longitudinal cross sectional view of the substrate processing apparatus shown in FIG. 1;

FIG. 4 is a flowchart showing a substrate processing method according to the exemplary embodiment;

FIG. 5A to FIG. 5C are schematic longitudinal cross sectional views illustrating an example of a substrate carrying-in operation in a drying module provided in the substrate processing apparatus shown in FIG. 1;

FIG. 6A and FIG. 6B are schematic longitudinal cross sections views illustrating an example flow of a fluid in a drying processing in the drying module;

FIG. 7A is a side view of the drying module, illustrating an example configuration and operation of a cover body and a lock key provided in the drying module, with the cover body located at a closing position and the lock key located at a lock position;

FIG. 7B is a cross sectional view of the drying module shown in FIG. 7A, taken along a line VIIB-VIIB;

FIG. 8A is a side view illustrating the drying module shown in FIG. 7A, with the cover body located at a standby position and the lock key located at a lock release position;

FIG. 8B is a cross sectional view of the drying module shown in FIG. 8A, taken along a line VIIIB-VIIIB;

FIG. 9A is a cross sectional view illustrating an example configuration and operation of the lock key and members around it in the drying module, with the lock key located at the lock release position;

FIG. 9B is a cross sectional view illustrating a state where the lock key shown in FIG. 9A has been moved to the lock position;

FIG. 10 is a cross sectional view illustrating an example configuration where a resin layer and a rolling body are provided on a surface of the lock key in a region X in FIG. 9A;

FIG. 11 is a flowchart illustrating an example of sub-processes of a process S4 in the flowchart of FIG. 4;

FIG. 12A to FIG. 12E are schematic diagrams illustrating an example mechanism in which wear particles derived from the lock key are generated and adhere to the substrate;

FIG. 13A and FIG. 13B are schematic diagrams illustrating a configuration and operation of a lock key cleaning device according to a first exemplary embodiment;

FIG. 14 is a schematic diagram illustrating a configuration and operation of a lock key cleaning device according to a second exemplary embodiment;

FIG. 15A and FIG. 15B are schematic diagrams illustrating a configuration and operation of a lock key cleaning device according to a third exemplary embodiment; and

FIG. 16 A to FIG. 16C are schematic diagrams illustrating a configuration and operation of a lock key cleaning device according to a fourth exemplary embodiment.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, exemplary embodiments of the present disclosure will be described with reference to the accompanying drawings, which form a part hereof. In the various drawings, same or corresponding parts will be assigned same or corresponding reference numerals, and redundant descriptions thereof will be omitted. In the present specification, the X-axis direction, the Y-axis direction, and the Z-axis direction are orthogonal to each other. The X-axis and Y-axis directions are horizontal directions, whereas the Z-axis direction is a vertical direction.

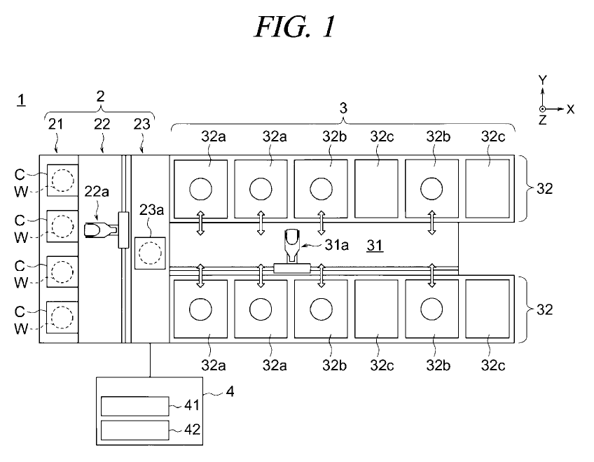

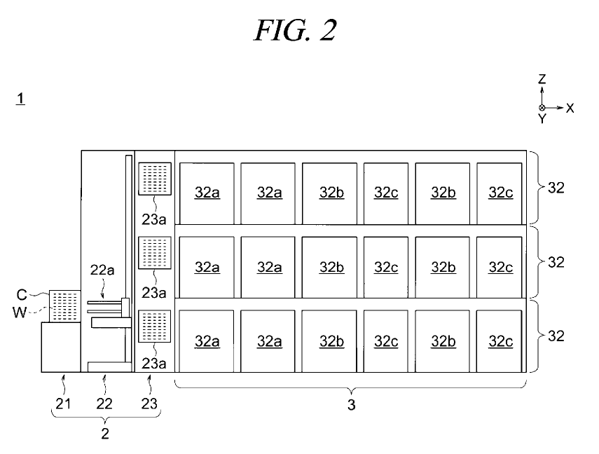

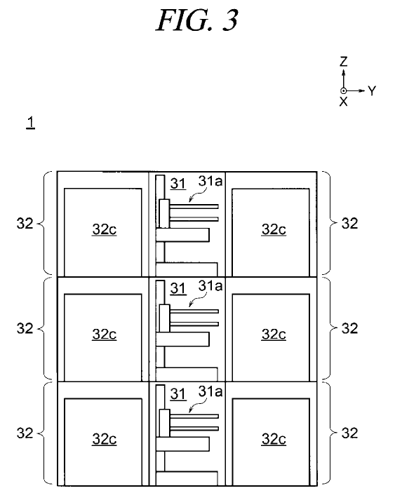

First, referring to FIG. 1 to FIG. 3, a substrate processing apparatus 1 according to an exemplary embodiment will be explained. As shown in FIG. 1, the substrate processing apparatus 1 includes a carry-in/out station 2 and a processing station 3.

The carry-in/out station 2 is equipped with a placement table 21, a transfer section 22, and a delivery section 23. Multiple carriers C are placed on the placement table 21. Each of the multiple carriers C accommodates a plurality of substrates W horizontally with the substrates W spaced apart from each other in a vertical direction.

The substrate W may include a semiconductor substrate such as a silicon wafer or compound semiconductor wafer, or a glass substrate. The substrate W may further include a device such as an electronic circuit formed on a surface of the semiconductor or glass substrate. The substrate W may also have an irregularity pattern on its surface.

The transfer section 22 incorporates a first transfer device 22a. The first transfer device 22a transfers the substrate W within the transfer section 22, and transfers the substrate W to/from multiple devices disposed next to the transfer section 22.

The first transfer device 22a includes a first transfer arm for holding the substrate W. The first transfer arm is movable in horizontal directions (both the X-axis direction and the Y-axis direction) and a vertical direction, and is pivotable around a vertical axis. There may be one or more first transfer arms.

The delivery section 23 has a transition device 23a for accommodating the substrate W temporarily.

The processing station 3 is equipped with a transfer block 31 and a plurality of processing blocks 32. The transfer block 31 is of a rectangular parallelepiped shape. The transfer block 31 incorporates a second transfer device 31a. The second transfer device 31a serves to transfer the substrate W between a plurality of devices disposed next to the transfer block 31.

The second transfer device 31a includes a second transfer arm for holding the substrate W. The second transfer arm is movable in horizontal directions (both the X-axis direction and the Y-axis direction) and a vertical direction, and is pivotable around a vertical axis. There may be one or more second transfer arms.

A plurality of such processing blocks 32 may be provided. As shown in FIG. 1, the plurality of processing blocks 32 may be symmetrically arranged at both sides of the transfer block 31 in the Y-axis direction.

The processing block 32 includes a liquid film forming module 32a, a drying module 32b, and a supplying module 32c. The processing block 32 may include multiple sets (for example, two sets) each including the liquid film forming module 32a, the drying module 32b and the supplying module 32c.

The liquid film forming module 32a supplies a liquid onto a top surface of the substrate W horizontally held. The liquid film forming module 32a includes, by way of example, a spin chuck for holding the wafer W horizontally, and a nozzle for discharging the liquid onto the top surface of the substrate W. The nozzle supplies the liquid to the center of the top surface of the substrate W being rotated. The liquid diffuses from the center of the top surface of the substrate W toward a periphery thereof due to a centrifugal force. As an example of the liquid, a chemical liquid, a rinse liquid and a drying liquid are supplied in this order. Multiple types of chemical liquids may be supplied, and the rinse liquid may be supplied between the supply of one chemical liquid and the supply of another chemical liquid.

In the liquid film forming module 32a, a liquid film of the chemical liquid is formed on the top surface of the horizontally held substrate W; the liquid film of the chemical liquid is replaced by a liquid film of the rinse liquid; and the liquid film of the rinse liquid is replaced by a liquid film of the drying liquid. The chemical liquid may be, by way of non-limiting example, SC1 (an aqueous solution of ammonia and hydrogen peroxide) or dilute hydrofluoric acid (DHF). The rinse liquid may be, by way of non-limiting example, deionized water (DIW). The drying liquid may be, for example, an organic solvent such as isopropyl alcohol (IPA).

The drying module 32b dries the substrate W by replacing the liquid film formed on the top surface of the horizontally held substrate W with a supercritical fluid. The supercritical fluid is a fluid subjected to a temperature above its critical temperature and a pressure above its critical pressure. By replacing the liquid film of the drying liquid or the like with the supercritical fluid, a collapse of the irregularity pattern of the substrate W, which might be caused by a surface tension, can be suppressed. Details of the drying module 32b will be discussed later.

The supplying module 32c supplies a fluid to the drying module 32b. To elaborate, the supplying module 32c is equipped with a supply device group including a flowmeter, a flow rate controller, a back pressure valve, a heater, and so forth, and has a housing accommodating the supply device group. The supplying module 32c supplies, for example, high-pressure CO₂ into the drying module 32b as the fluid.

When viewed from the top, the drying modules 32b and the supplying modules 32c belonging to the same processing block 32 are alternately arranged in the X-axis direction. The supplying module 32c supplies the fluid to the drying module 32b adjacent thereto on its negative X-axis side.

When viewed from the top, the processing block 32 is protruded more than the transfer block 31 in the positive X-axis direction. The supplying module 32c is disposed in this protruding portion. The supplying module 32c is open on its three sides (positive Y-axis, negative Y-axis, and positive X-axis sides), which facilitates maintenance operations.

In case that the plurality of processing blocks 32 are provided, the second transfer device 31a transfers the single substrate W between multiple modules (for example, the liquid film forming module 32a and the drying module 32b) belonging to the same processing block 32.

The substrate processing apparatus 1 is equipped with a control device 4 (shown only in FIG. 1). The control device 4 is capable of controlling the operations of all operable components included in the substrate processing apparatus 1. The control device 4 is, for example, a computer, and is equipped with a control processor 41 and a storage 42. The storage 42 stores therein a program (including processing recipes) for controlling various types of processes performed in the substrate processing apparatus 1. The control processor 41 controls the operation of the substrate processing apparatus 1 by reading and executing the program stored in the storage 42. The control processor 41 may be a central processing unit (CPU), and may be one or more circuits.

Here, the program as described above may have been recorded on a computer-readable recording medium, and may be installed from that recording medium into the storage 42 of the control device 4. The computer-readable recording medium may be, by way of example, one of a hard disk (HD), a flexible disk (FD), a compact disk (CD), a magnetic optical disk (MO), a memory card, a random access memory (RAM), a read-only memory (ROM), and a solid-state drive (SSD), or a combination of two or more of these.

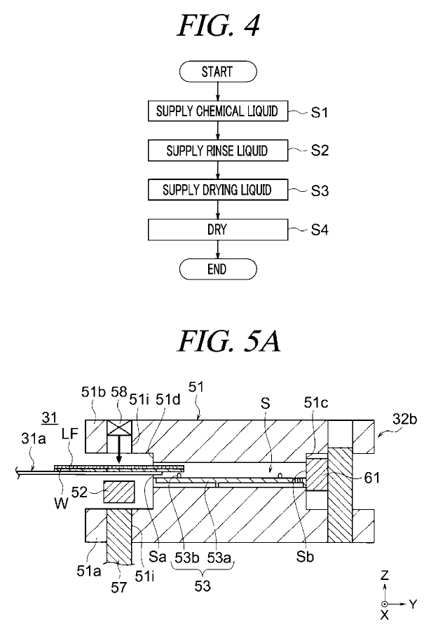

Now, the operation of the substrate processing apparatus 1 will be explained with reference to FIG. 4. Processes S1 to S4 shown in FIG. 4 are performed under the control of the control device 4.

First, the first transfer device 22a takes out the substrate W from the carrier C and transfers it to the transition device 23a. Then, the second transfer device 31a takes out the substrate W from the transition device 23a, and transfers it to the liquid film forming module 32a.

Subsequently, the liquid film forming module 32a supplies the chemical liquid onto the top surface of the substrate W which is horizontally held (process S1). The chemical liquid is supplied to the center of the top surface of the substrate W being rotated, and diffused onto the entire top surface of the substrate W in a radial direction by the centrifugal force, thus forming a liquid film.

Thereafter, the liquid film forming module 32a supplies the rinse liquid onto the top surface of the substrate W which is held horizontally (process S2). The rinse liquid is supplied to the center of the top surface of the substrate W being rotated, and diffused onto the entire top surface of the substrate W in the radial direction by the centrifugal force, thus forming a liquid film. As a result, the liquid film of the chemical liquid is replaced by the liquid film of the rinse liquid.

Next, the liquid film forming module 32a supplies the drying liquid onto the top surface of the substrate W which is held horizontally (process S3). The drying liquid is supplied to the center of the top surface of the substrate W being rotated, and diffused onto the entire top surface of the substrate W in the radial direction by the centrifugal force, thus forming a liquid film. As a result, the liquid film of the rinse liquid is replaced by the liquid film of the drying liquid.

Then, the second transfer device 31a takes out the substrate W from the liquid film forming module 32a, and transfers the taken substrate W into the drying module 32b.

Subsequently, the drying module 32b dries the substrate W by replacing the liquid film formed on the top surface of the horizontally held substrate W with the supercritical fluid (process S4). If the liquid film of the drying liquid or the like is replaced by the supercritical fluid, appearance of a liquid-gas interface at the irregularity pattern of the substrate W can be suppressed. As a result, generation of a surface tension can be suppressed, so that a collapse of the irregularity pattern can be suppressed.

Finally, the second transfer device 31a takes out the substrate W from the drying module 32b, and transfers the taken substrate W into the transition device 23a. Then, the first transfer device 22a takes out the substrate W from the transition device 23a, and stores the taken substrate W in the carrier C.

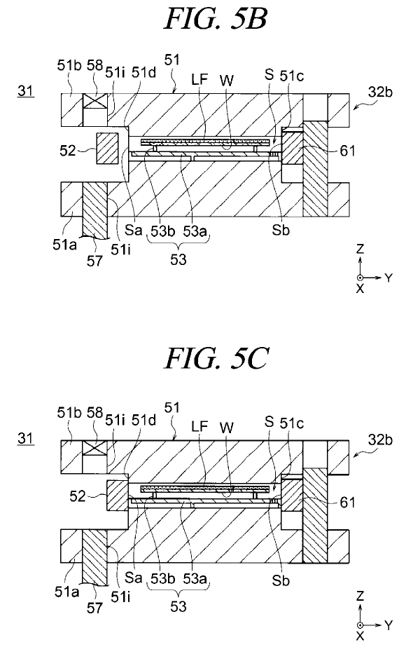

Now, a configuration and operation of the drying module 32b will be explained with reference to FIG. 5 A to FIG. 5C, which are cross sectional views obtained by cutting a central portion of the drying module 32b in the X-axis direction along a plane parallel to the YZ plane. The drying module 32b shown in FIG. 5A to FIG. 5C is disposed on the positive Y-axis side of the transfer block 31. In the description of the drying module 32b, a direction in which the substrate W is carried into a drying chamber S (i.e., the positive Y-axis direction in FIG. 5 A to FIG. 5C) is referred to as a front side, and a direction in which the substrate W is carried out from the drying chamber S (i.e., the negative Y-axis direction in FIG. 5 A to FIG. 5C) is referred to as a rear side.

The drying module 32b is equipped with a pressure vessel 51 having therein the drying chamber S for the substrate W, a cover body 52 for closing a first opening Sa of the drying chamber S, and a support body 53 fixed inside the drying chamber S to hold the substrate W horizontally in the drying chamber S. The first opening Sa is a carry-in/out opening for the substrate W. The substrate W is carried into the drying chamber S through the first opening Sa, dried in the drying chamber S, and then carried out of the drying chamber S through the first opening Sa.

As an example, the pressure vessel 51 includes a lower wall 51a, an upper wall 51b, a front wall 51c, a rear wall 51d, and a pair of sidewalls, and has the drying chamber S therein. One of the sidewalls is an inner wall of the drying chamber S in FIG. 5A to FIG. 5C. The drying chamber S is of, by way of non-limiting example, a rectangular parallelepiped shape. The first opening Sa having a rectangular shape is formed in the rear wall 51d, and a second opening Sb having a rectangular shape is formed in the front wall 51c.

The cover body 52 is provided at the rear of the rear wall 51d. The cover body 52 is configured to be moved back and forth between a closing position (the position shown in FIG. 5C) and an opening position (the position shown in FIG. 5B). The closing position is a position where the cover body 52 closes the first opening Sa. The opening position is located at the rear of the closing position, and is a position where the cover body 52 opens the first opening Sa.

The second opening Sb is closed by a cover body 61. The cover body 61 is configured to be opened or closed. In a normal operation mode of the drying module 32b, the cover body 61 is kept closed, but it can be opened during the maintenance of the drying module 32b, for example.

To allow the second transfer device 31a to easily advance into the drying chamber S, the cover body 52 can be rotated between the opening position and a standby position (the position shown in FIG. 5A). The standby position is a position deviated from movement paths of the substrate W and the transfer arm during the carrying-in and carrying-out of the substrate W. During the carrying-in and carrying-out of the substrate W, the cover body 52 stands by at the standby position.

The support body 53 includes a rectifying plate 53a, and support pins 53b provided on a top surface of the rectifying plate 53a. The rectifying plate 53a is fixed to the wall of the pressure vessel 51. The rectifying plate 53a guides and rectifies a flow of the fluid in the drying chamber S. The support pins 53b support the substrate W on their top surfaces. A gap exists between the substrate W and the rectifying plate 53a.

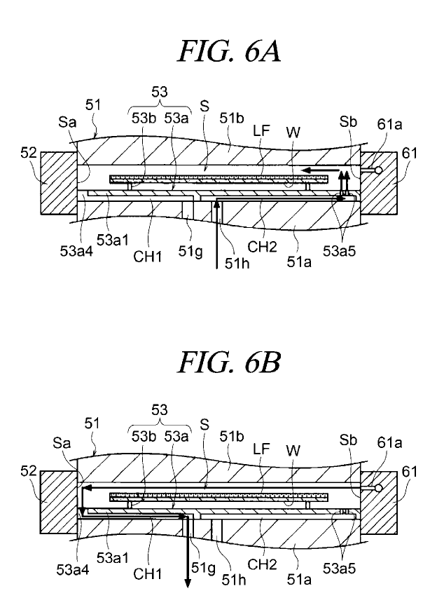

FIG. 6A and FIG. 6B show members associated with the supply and the drainage of the fluid, which are not shown in FIG. 5A to FIG. 5C, providing an enlarged view near the substrate W. As depicted in the drawings, a drain port 51g for draining the fluid from the drying chamber S and a supply port 51h for supplying the fluid into the drying chamber S are provided in the lower wall 51a of the pressure vessel 51. The second cover body 61 is provided with a plurality of discharge openings 61a for the fluid, which are arranged at approximately equal intervals in a direction perpendicular to the plane of the drawing (the X-axis direction) of FIG. 6A.

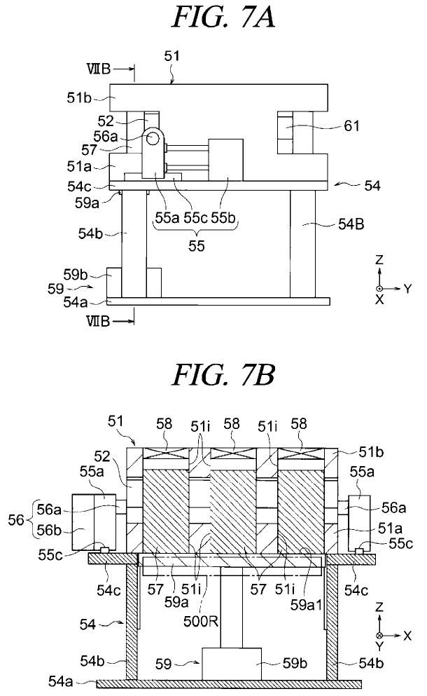

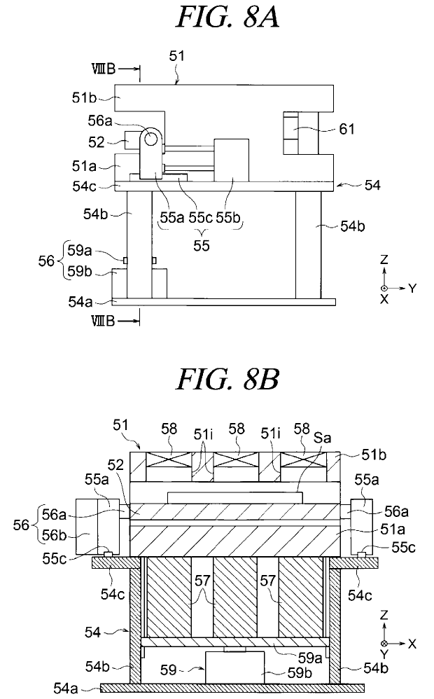

As illustrated in FIG. 7 A to FIG. 8 B, the drying module 32b is equipped with a support frame 54 supporting the pressure vessel 51. The support frame 54 includes, by way of example, a base plate 54a that is horizontal, a plurality of pillars 54b protruding upwards from the base plate 54a, and a pair of horizontal plates 54c fixed to top surfaces of the plurality of pillars 54b. The pressure vessel 51 is fixed on the pair of horizontal plates 54c that are arranged apart from each other in the X-axis direction.

The drying module 32b is also equipped with a linearly moving mechanism 55 configured to move the cover body 52 back and forth between the closing position and the opening position, and a rotating mechanism 56 configured to rotate the cover body 52 between the opening position and the standby position. The rotating mechanism 56 includes, for example, rotation shafts 56a of the cover body 52, and a rotary actuator 56b for rotating the rotation shafts 56a. Meanwhile, the linearly moving mechanism 55 includes sliders 55a holding bearings of the rotation shafts 56a, and a linearly moving actuator 55b for moving the sliders 55a back and forth.

The rotation shafts 56a of the cover body 52 are symmetrically arranged in the X-axis direction with the cover body 52 therebetween. The sliders 55a are also symmetrically arranged in the X-axis direction with the cover body 52 therebetween. Guides 55c of the sliders 55a are respectively mounted on the pair of horizontal plates 54c. The rotary actuator 56b is fixed to one of the sliders 55a and moved back and forth along with this slider 55a. The linearly moving actuator 55b is fixed to one of the horizontal plates 54c.

The linearly moving actuator 55b is, by way of non-limiting example, a pneumatic cylinder, and serves to press the cover body 52 against the pressure vessel 51 with the pressure of compressed air. A non-illustrated seal member for sealing a gap between the cover body 52 and the pressure vessel 51 can be pressed by the driving force of the linearly moving actuator 55b, so that the cover body 52 can be suppressed from obstructing a movement of the lock key 57 when the lock key 57 to be described later is fitted into an insertion hole 51i of the upper wall 51b of the pressure vessel 51. Further, the linearly moving actuator 55b may include a motor, and a ball screw that converts a rotary motion of the motor into a linear motion of the cover body 52.

The drying module 32b is equipped with the lock key 57 configured to restrict the cover body 52 from being retreated from the closing position toward the opening position. The lock key 57 is fitted in a wedge shape into the insertion hole 51i of the pressure vessel 51, thereby restricting (substantially prevents) the retreat of the cover body 52. Thus, even when the pressure of the drying chamber S rises as a result of supplying the fluid into the drying chamber S, the retreat of the cover body 52 can be restricted, so that a leak of the fluid can be suppressed.

The lower wall 51a and the upper wall 51b protrude backwards, as compared to the rear wall 51d. In these protruding portions, the insertion hole 51i is formed through the lower wall 51a and the upper wall 51b in the Z-axis direction. A plurality of such insertion holes 51i are provided, and these insertion holes 51i are arranged at intervals therebetween in the X-axis direction. The lock key 57 may also be provided in plural numbers, and these lock keys 57 are arranged at intervals therebetween in the X-axis direction. Each of these lock keys 57 is fitted into the corresponding insertion holes 51i formed in the lower wall 51a and the upper wall 51b.

Although not particularly limited, the number of the lock keys 57 may be three, for example. Unlike in a case where only two lock keys 57 are provided, a central portion of the cover body 52 in the X-axis direction can also be pressed. As a result, when increasing the pressure of the drying chamber S by supplying the fluid into the drying chamber S, the central portion of the cover body 52 in the X-axis direction can be suppressed from bulging backwards more than an end portion of the cover body 52 in the X-axis direction.

The drying module 32b may also be equipped with a laser film thickness meter 58 for measuring the thickness of the liquid film LF formed on the top surface of the substrate W carried into the drying chamber S of pressure vessel 51.

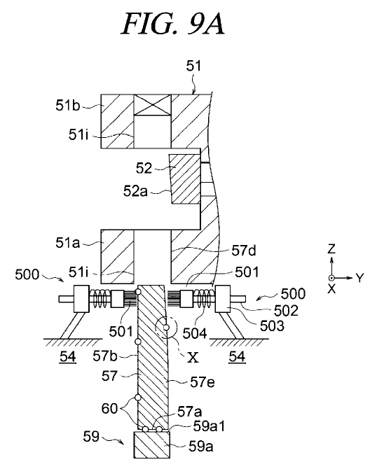

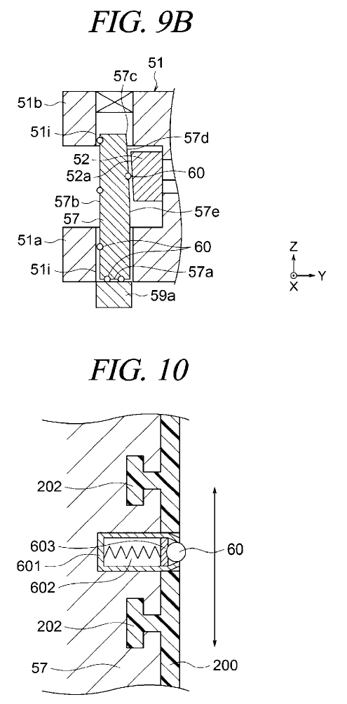

The drying module 32b is equipped with an elevation mechanism 59 configured to move the lock key 57 up and down between a lock position (the position shown in FIG. 9B) and a lock release position (the position shown in FIG. 9A). The lock position is a position where the lock key 57 restricts the retreat of the cover body 52 and the lock key 57 is fitted into the insertion holes 51i in both the lower wall 51a and the upper wall 51b. The lock release position is a position where the lock key 57 allows the retreat of the cover body 52 and the lock key 57 is pulled downwards from the insertion holes 51i in the upper wall 51b and the lower wall 51a. The lock release position is set below the lower wall 51a of the pressure vessel 51 not only to suppress interference between the lock key 57 and the substrate W but also to provide a lock key cleaning device to be described later.

The elevating mechanism 59 includes, for example, an elevating table 59a on which the lock keys 57 are arranged, and a linear moving actuator 59b configured to move the elevating table 59a up and down. The elevating table 59a has a horizontal surface 59a1 on which the lock keys 57 are placed. The linearly moving actuator 59b is, for example, a pneumatic cylinder, and serves to move the lock keys 57 up and down by moving the elevating table 59a up and down. The linearly moving actuator 59b may include a motor, and a ball screw that converts a rotary motion of the motor into a linear motion of the elevating table 59a.

In an area 500R enclosed by a dashed dotted line in FIG. 7B, a brush of the lock key cleaning device for cleaning the lock key 57 is provided. The lock key cleaning device is mainly intended to remove wear particles adhering to the lock key 57. A specific configuration of the lock key cleaning device will be explained in detail later.

As shown in FIG. 9A, a rolling body 60 may be provided at the lock key 57. The rolling body 60 may be, by way of example, a ball, and is held so as to be rotatable around its center. Alternatively, the rolling body 60 may be a roller.

When the elevating mechanism 59 raises the lock key 57 from the lock release position to the lock position, the rolling body 60 rolls while being in contact with the cover body 52 or the pressure vessel 51. The rolling body 60 serves to reduce frictional resistance, so that particle generation due to friction can be suppressed.

A plurality of such rolling bodies 60 may also be provided at a bottom surface 57a of the lock key 57, and they roll while being in contact with the horizontal surface 59a1 of the elevating mechanism 59. Thus, when raising the lock key 57, the lock key 57 can be horizontally moved within the insertion holes 51i, so that frictional resistance can be reduced.

It is desirable to move the lock key 57 up and down with its rear surface 57b standing upright. The lock key 57 can be raised with its rear surface 57b tilted forwards. In such a case, however, an edge 57c at a front end of the top surface of the lock key 57 may come into collision with the rear surface 52a of the cover body 52.

A plurality of rolling bodies 60 are provided at the rear surface 57b of the lock key 57 at an interval in the Z-axis direction. As compared to a case where only one rolling body is provided, the friction between lock key 57 and the pressure vessel 51 can be suppressed. This configuration is particularly useful when the rear surface 57b of lock key 57 is set up upright.

As shown in FIG. 9B, the lock key 57 may have, on a front surface thereof, an inclined surface 57d that is inclined forwards as it goes downwards from an upper end thereof, and a vertical surface 57e extending directly downwards from a lower end of the inclined surface 57d. Due to the presence of this inclined surface 57d, the edge 57c at the front end of the top surface of the lock key 57 may be suppressed from colliding with the rear surface 52a of the cover body 52.

The rolling body 60 may also be provided at the inclined surface 57d of the lock key 57, and it rolls in contact with the rear surface 52a of the cover body 52. The rear surface 52a of the cover body 52 faces the inclined surface 57d of the lock key 57 and is inclined forwards as it goes downwards from an upper end thereof.

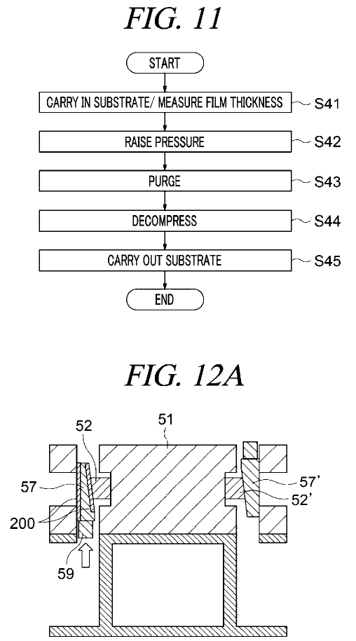

Now, details of the process S4 described in FIG. 4 will be discussed with reference to FIG. 11. Processes (sub-processes) S41 to S45 shown in FIG. 11 are performed under the control of the control device 4.

First, the second transfer device 31a horizontally holds the substrate W having the liquid film LF of the drying liquid formed thereon, and carries the substrate W into the drying chamber S inside the pressure vessel 51 (process S41). In this process, the laser film thickness meter 58 measures the film thickness of the liquid film LF, whereby it can be verified whether the irregularity pattern of the substrate W is covered with the liquid film LF.

Then, the support body 53 fixed to the drying chamber S receives the substrate W from the second transfer device 31a, and holds the received substrate W horizontally. Subsequently, the second transfer device 31a is retreated to the outside of the drying chamber S through the first opening Sa of the drying chamber S.

Next, the rotating mechanism 56 rotates the cover body 52 from the standby position to the opening position. Then, the linearly moving mechanism 55 moves the cover body 52 forwards from the opening position to the closing position. As a result, the cover body 52 closes the first opening Sa of the drying chamber S.

Thereafter, the elevating mechanism 59 raises the lock keys 57 from the lock release position to the lock position. The lock keys 57 press the cover body 52 from the rear side thereof, thus restricting the cover body 52 from being retreated. Thus, in the process S42 to be described later, a leak of a fluid can be suppressed.

Next, the supplying module 32c supplies the fluid such as CO₂ into the drying chamber S, thus raising the pressure of the drying chamber S (process S42). The fluid is supplied into the drying chamber S from the supply port 51h of the lower wall 51a, as shown in FIG. 6A. The fluid is discharged upwards from supply openings 53a5 of the rectifying plate 53a. Although not shown, when viewed from the top, the supply openings 53a5 are formed in plural numbers at each of the four corners of the rectifying plate 53a, and the fluid flows from an outer side of the substrate W toward an inner side thereof. A flow of the fluid heading toward the center of the substrate W from the periphery thereof is formed above the substrate. This flow of the fluid suppresses the liquid film LF from flowing the outside of the substrate W. When viewed from the top, since the supply openings 53a5 are positioned at the outer side than the substrate W, the substrate W is not shaken even when the supply openings 53a5 discharge the fluid directly upwards. While increasing the pressure of the drying chamber S, the fluid is not drained from the drying chamber S but stored in the drying chamber S. The pressure of the drying chamber S is raised up to a set pressure equal to or higher than a critical pressure.

Next, while maintaining the pressure of the drying chamber S at the preset pressure by supplying the fluid into the drying chamber S with the supplying module 32c and draining the fluid from the drying chamber S with a non-illustrated draining module, a drying liquid dissolved in the fluid in a supercritical state is discharged from the drying chamber S (process S43). At this time, the fluid is supplied into the drying chamber S from the discharge openings 61a provided at the second cover body 61 at the regular interval in the X-axis direction. As shown in FIG. 6B, the fluid flows in a curtain shape above the substrate W and is introduced into a space below the rectifying plate 53a through a drain opening 53a4 of the rectifying plate 53a, and is finally drained to the outside of the drying chamber S through the drain port 51g. When the fluid flows above the substrate W, the liquid forming the liquid film LF is replaced by the supercritical fluid.

Thereafter, the supply of the fluid into the drying chamber S is stopped, and the inside of the drying chamber S is decompressed to an atmospheric pressure or thereabout by opening the drying chamber S to the atmosphere, for example, thus allowing the supercritical fluid to be vaporized and drained from the drying chamber S to dry the substrate W (process S44).

Then, the elevating mechanism 59 lowers the lock keys 57 from the lock position to the lock release position. At this time, wear particles adhering to the lock key 57 are removed by the lock key cleaning device 500, as will be elaborated later.

Next, the linearly moving mechanism 55 retreats the cover body 52 from the closing position to the opening position. Subsequently, the rotating mechanism 56 rotates the cover body 52 from the opening position to the standby position.

Thereafter, the second transfer device 31a advances into the drying chamber S inside the pressure vessel 51, receives the substrate W from the support body 53, and carries out the received substrate W (process S45).

For further details on the technical matters explained so far in the specification of the present application, please refer to Patent Document 1 (Japanese Patent Laid-open Publication No. 2022-030850) filed by the applicant of the present application. The technical matters described in Patent Document 1 are also applicable to the substrate processing apparatus 1 of the present application.

Hereinafter, the configuration of the lock key 57 will be explained in further detail.

Desirably, the rolling body 60 provided at the lock key 57 is configured so that it can retract from the surface of the lock key 57. When the pressure in the drying chamber S of the pressure vessel 51 rises to the supercritical pressure of CO₂ (approximately 16 MPa), the cover body 52 attempts to open due to this pressure. If this cover body 52 is supported only by the rolling body 60, which is in point contact with the cover body 52, the rolling body 60 could be damaged. As a resolution, if the lock key 57 and the rolling body 60 lie on the same plane when the rolling body 60 retracts and as a result, the lock key 57 and the member facing it (such as the cover body 52) come into contact, there would be no risk of damage to the rolling body 60.

To enable the rolling body 60 to retract from the surface of the lock key 57, a ball plunger-shaped mechanical element (hereinafter referred to as "ball plunger" for simplicity) as shown in FIG. 10 may be used as a configuration example. The ball plunger has a structure in which the ball (rolling body) 60, biased by a spring 602, is mounted in a rotatable manner inside a sleeve 601 (cylindrical body). An inlet of the sleeve 601 has a diameter slightly smaller than that of the ball 60, which suppresses the ball 60 from escaping out of the sleeve 601. The sleeve 601 of the ball plunger is accommodated in a hole formed in the lock key 57. A male thread may be formed on an outer surface of the sleeve of the ball plunger, and this male thread may be fitted into a threaded hole formed in the lock key 57. To reduce the amount of wear particles generated between the ball and the ball plunger in contact with it, the ball may be put in the sleeve of the ball plunger while being held by a resin holder or support 603. In this case, the resin holder or support is stored in the sleeve while being spring-loaded. When the ball (rolling body) 60 is pressed, it retracts into the sleeve 601 while compressing the spring 602.

If the rolling body 60 is made retractable, the material forming the rolling body 60 is not limited to a steel material such as tool steel, but can also be engineering plastic or ceramic.

In addition to or instead of providing the lock key 57 with the rolling body 60, a resin layer 200 may be provided on a portion of the surface of the lock key 57 (specifically, the inclined surface 57d and the rear surface 57b) that is subjected to a high load caused by the supercritical pressure inside the drying chamber S. By providing the resin layer 200, generation of metal wear particles due to sliding contact between metal pieces under a high surface pressure (which will be described in detail later) can be suppressed. If such metal wear particles adhere to the substrate W, the substrate W is highly likely to suffer a problem. When both the rolling body 60 and the resin layer 200 are provided, it is desirable to configure the rolling body 60 so that it can retract to a position where it lies on the same plane with the resin layer 200. FIG. 10 schematically illustrates a configuration example in which both the rolling body 60 and the resin layer 200 are provided on the surface of the lock key 57.

The material forming the resin layer 200 desirably has strength sufficient to withstand a relatively high surface pressure without deformation, and also desirably has a low coefficient of friction. Examples of the material suitable for the resin layer 200 include polyether ether ketone (PEEK), nylon, or high-density polypropylene.

The resin layer 200 can be formed of a resin plate having a thickness of 1 mm to several mm. As shown in FIG. 10, by providing complementary irregularities 202 on the resin layer 200 and the lock key 57, it is possible to suppress the resin layer 200 from being deviated and separated from the lock key 57 due to a shear force when the lock key 57 slides into contact with an opposing member (e.g., the rear surface 52a of the cover body 52). In one configuration example, an arrow in FIG. 10 indicates the elevating direction of the lock key 57 (Z-axis direction), and the irregularities 202 extend in a direction perpendicular to the elevating direction of the lock key 57. The complementary irregularities 202 may be, by way of example, a T-shaped protrusion provided on a rear surface of the resin layer 200 and a T-shaped recess formed on a front surface of lock key 57, but are not limited thereto.

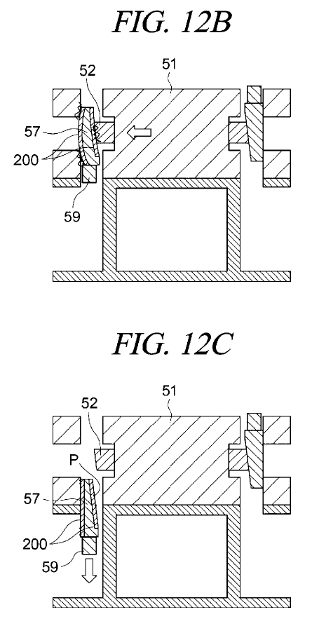

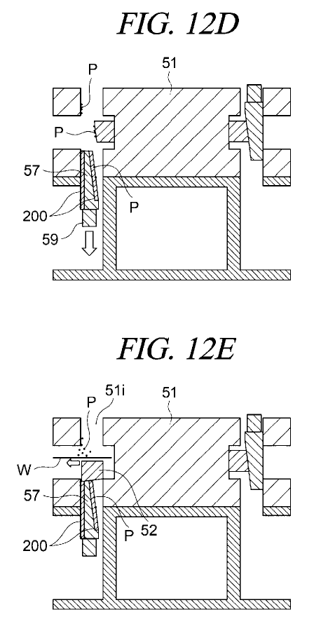

Now, the mechanism by which wear particles from the lock key 57 (particularly wear particles from the resin layer 200) adhere to the substrate W, which is briefly mentioned above, will be explained with reference to FIG. 12A to FIG. 12E.

After the substrate W to be subjected to a drying processing is placed in the drying chamber S of the pressure vessel 51, the cover body 52 is closed. Then, as shown in FIG. 12A, the lock key 57 is raised from the lock release position to the lock position. Just before the lock key 57 reaches the lock position, the inclined surface 57d and the rear surface 57b (on which the resin layer 200 is provided) slide against their opposing surfaces, that is, the rear surface 52a of the cover body 52 and the inner surface of the insertion hole 51i (which are made of metals) due to a wedge action. Even in the case where the rolling body 60 is provided, the rolling body 60 retracts and becomes coplanar with the resin layer 200 just before reaching the lock position, allowing the above-described sliding to occur. At this time, the week resin layer 200 may be damaged, generating the wear particles resulting from the resin layer. However, the amount of the wear particles generated at this time is very small.

Subsequently, when the drying chamber S is filled with high-pressure CO₂ in a supercritical state, the cover body 52 is pressed against the lock key 57 with a large force (indicated by an arrow) of, e.g., about 20 tons, as illustrated in FIG. 12B. This causes the lock key 57 to be bent, which results in a sliding movement under a high pressure between the surface of the lock key 57 (the resin layer 200) and its opposing surface. This sliding movement causes a damage to the weak resin layer 200, resulting in the wear particles from the resin layer. Most of the problematic wear particles are generated at this time.

During the sliding movement, the resin layer 200 (here, made of PEEK) on the surface of the lock key 57 is charged, but the metal member that slides against it is hardly charged. Therefore, if the amount of wear particles generated is small, the wear particles will preferentially adhere to a surface of the resin layer 200 of the lock key 57, as shown in FIG. 12C. The wear particles hardly adhere to the metal member.

As the substrate W is repeatedly processed, the wear particles are deposited on the surface of the resin layer 200. When the wear particles are accumulated in quantity more than can be retained on the surface of the resin layer 200, some of the wear particles may also adhere to surfaces of the members that come into contact with the resin layer 200 of the lock key 57 (the rear surface 52a of the cover body 52 and the inner surface of the insertion hole 51i), as illustrated in FIG. 12D.

As shown in FIG. 12E, the wear particles adhering to, for example, the inner surface of the insertion hole 51i may fall off and adhere to the surface of the substrate W when the substrate W is carried into or out of the pressure vessel 51. The wear particles from the lock key 57 are generated and attached to the substrate W by the mechanism as described above.

Now, several embodiments of the lock key cleaning device 500 will be explained. Here, the explanation will be provided for an example where the resin layer 200 made of PEEK is provided on the surface of the lock key 57.

### [First exemplary embodiment of lock key cleaning device]

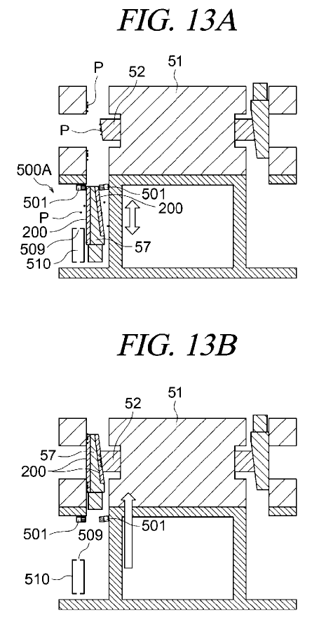

Referring to FIG. 13A and FIG. 13B, a lock key cleaning device 500A according to a first exemplary embodiment will be described.

The lock key cleaning device 500A according to the first exemplary embodiment has a brush 501 that cleans the lock key 57 by brushing it. Three lock keys 57 are provided in one drying module 32b, and at least one pair of such brushes 501 are provided for each lock key 57. One of the brushes 501 in pair (also referred to as "rear brush 501") cleans the rear surface 57b of the lock key 57, while the other (also referred to as "front brush 501") cleans the front surface (inclined surface 57d and the vertical surface 57e) of the lock key 57. In one configuration example, each brush 501 is elongated in a horizontal direction (elongated in the X-axis direction), and its width in the X-axis direction (width in the horizontal direction) is equal to or greater than the width of the corresponding lock key 57 in the X-axis direction.

The front brush 501 and the rear brush 501 are positioned so that they contact an upper end of the inclined surface 57d and an upper end of the rear surface 57b of the lock key 57, respectively, when the lock key 57 is at the lock release position. As stated above, when the lock key 57 is at the lock release position, the upper end of the lock key 57 is desirably located lower than the lower surface of the lower wall 51a of the pressure vessel 51.

During the brush cleaning, the lock key 57 is moved up and down by the elevating mechanism 59 at least once, and desirably multiple times, thereby allowing at least the area of the lock key 57 where the resin layer 200 is provided is scrubbed by the brush 501, so that the wear particles (hereinafter sometimes denoted by "P") adhering to the resin layer 200 of the lock key 57 are removed.

The brush 501 may be spring-biased toward the lock key 57 to ensure that the brush 501 comes into contact with the lock key 57. This configuration is advantageous for performing secure cleaning of the inclined surface 57d, since the lock key 57 is tapered so that its leading ends narrows upwards.

As a specific example, as shown in FIG. 9A, a brush shaft 502 connected to the brush 501 is supported by a brush guide 503 so that it can slide in the Y-axis direction. The brush guide 503 is fixed directly to the support frame 54 or to a bracket fixed to the support frame 54. A coil spring 504 is placed in a compressed state between the brush 501 and the brush guide 503, and the brush 501 is pressed against the lock key 57 by a restoring force of the coil spring 504.

When the lock key 57 is rubbed with the brush 501, the resin layer 200 may be charged (but may not sometimes) depending on the combination of the materials of the brush 501 and the resin layer 200. In this case, when there exist the wear particles adhering to the surfaces of the pressure vessel 51 and the cover body 52 that come into contact with the lock key 57 at the lock position, these wear particles are moved (attached) to the charged resin layer 200 when the lock key 57 is moved to the lock position. For this reason, the lock key 57 may be moved back and forth between the lock release position and the lock position one or more times, desirably multiple times, while performing the suction described above. As a result, the wear particles adhering to the surfaces of the pressure vessel 51 and the cover body 52 can also be removed.

To collect the wear particles scraped off the lock key 57 by the brush 501, it is desirable to provide a local exhaust duct 510 in an area where the wear particles may float. The local exhaust duct 510 is connected to, for example, a plant exhaust system (exhaust duct) installed in a semiconductor manufacturing plant, and the inside of this local exhaust duct 510 set under a negative pressure. Therefore, if this local exhaust duct 510 is provided with an appropriate opening 509 (opening for suction), most of the wear particles floating around the local exhaust duct 510 can be collected.

### [Second exemplary embodiment of lock key cleaning device]

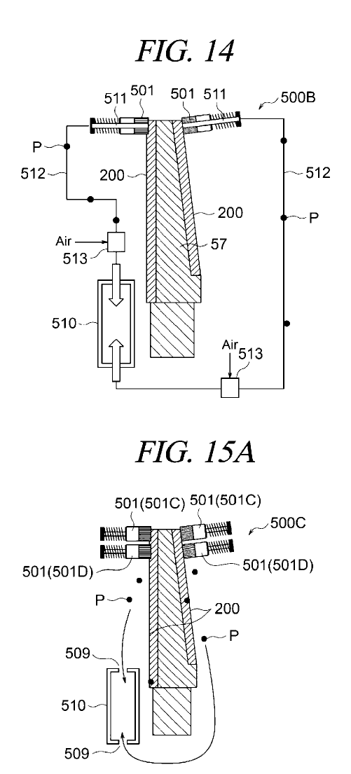

Referring to FIG. 14, a lock key cleaning device 500B according to a second exemplary embodiment will be discussed.

The lock key cleaning device 500B of the second exemplary embodiment is different from the lock key cleaning device 500A of the first exemplary embodiment in that a suction force is applied to the brush 501 so that the wear particles scrubbed off by the brush 501 are sucked in to be collected. Other features are the same as those of the first exemplary embodiment.

In this second exemplary embodiment, an air passage 511 serving as a suction path is provided inside the brush 501 (more specifically, a base portion of the brush where brush bristles (filaments) are provided). An upstream end (intake opening) of the air passage 511 is enclosed by the brush bristles (filaments).

An upstream end of a suction line 512 is connected to the air passage 511 of the brush 501. The suction line 512 is provided with an ejector 513 configured to apply a suction force to the air passage 511 of the brush 501 to collect the wear particles scraped off by the brush 501. A downstream end of the suction line 512 is connected to the local exhaust duct 510.

In the same manner as in the first exemplary embodiment, the lock key 57 is moved up and down by the elevating mechanism 59, and at least during this time, the suction force is applied to the air passage 511 of the brush 501. The wear particles scraped off by the brush 501 is exhausted to the plant exhaust system through the air passage (suction path) 511, the suction line 512, and the local exhaust duct 510 in sequence. This eliminates a risk that the wear particles scraped off by the brush 501 may be scattered to the space around the lock key 57 at the lock release position.

As in the first exemplary embodiment, the configuration in which the wear particles that might float around the local exhaust duct 510 is directly sucked into the local exhaust duct 510 may also be adopted in the second exemplary embodiment.

### [Third exemplary embodiment of lock key cleaning device]

A lock key cleaning device 500C according to a third exemplary embodiment will be explained with reference to FIG. 15A and FIG. 15B.

The lock key cleaning device 500C of the third exemplary embodiment includes, as the brush 501, a pair of charging brushes and a pair of static elimination (discharging) brushes for each lock key 57. For convenience’ sake, the charging brush will hereinafter be referred to as "charging brush 501C" and the static elimination brush as "static elimination brush 501D."

The charging brush 501C (more specifically, the bristles (filaments) of the charging brush 501C) is made of a material that charges the resin layer 200 when it is rubbed against the resin layer 200. The static elimination brush 501D (more specifically, the bristles (filaments) of the static elimination brush 501D) is made of a material that eliminates the static electricity of the resin layer 200 when it is rubbed against the resin layer 200. As an example, when the resin layer 200 is PEEK, the bristles of the charging brush 501C are made of polypropylene, and the static elimination brush 501D is made of, for example, nylon. The order of chargeability of materials is known, and a ‘triboelectric series’ in which materials are listed in the order of chargeability from those tending to be positively charged to those tending to be negatively charged is also known. By referring to the triboelectric series, the materials of the bristles of the charging brush 501C and the static elimination brush 501D can be determined in relation to the material constituting the resin layer 200.

The charging brush 501C and the static elimination brush 501D are positioned adjacent to each other in the vertical direction, with the charging brush 501C located above the static elimination brush 501D. In this configuration, when the lock key 57 is lowered, when the resin layer 200 is vertically divided into multiple sections, and one section (referred to as "local section" for simplicity) is viewed locally, the charging brush 501C will first come into contact with the local section, followed by the static elimination brush 501D. Therefore, the local section, which is charged, is rubbed by the static elimination brush 501D, so that the wear particles adhering to the local section can be easily removed (see FIG. 15A).

On the other hand, when the lock key 57 is raised, the static elimination brush 501D first comes into contact with the local section of the resin layer 200, followed by the charging brush 501C. Therefore, as shown in FIG. 15B, by the time the lock key 57 has reached the lock position, the entire resin layer 200 is in the charged state. By bringing the charged resin layer 200 into contact with the surfaces of the pressure vessel 51 and the cover body 52, the wear particles adhering to the surfaces of the pressure vessel 51 and the cover body 52 can be moved to the resin layer 200. The wear particles moved to the resin layer 200 in this way can be removed from the resin layer 200 by the static elimination brush 501D during the process of moving the lock key 57 from the lock position to the lock release position.

According to the third exemplary embodiment described above, the wear particles adhering to the lock key 57 as well as those adhering to the pressure vessel 51 and cover body 52 can be removed efficiently.

In this third exemplary embodiment, as in the first exemplary embodiment, in order to collect the wear particles P scrapped off the lock key 57 by the brush 501 (the charging brush 501C and the static elimination brush 501D), the local exhaust duct 510 may be provided in the area where the wear particles P may be floating. Also, as in the second exemplary embodiment, a suction force may be applied to the brush 501 to suck in and collect the wear particles P scraped off by the brush 501.

### [Fourth exemplary embodiment of lock key cleaning device]

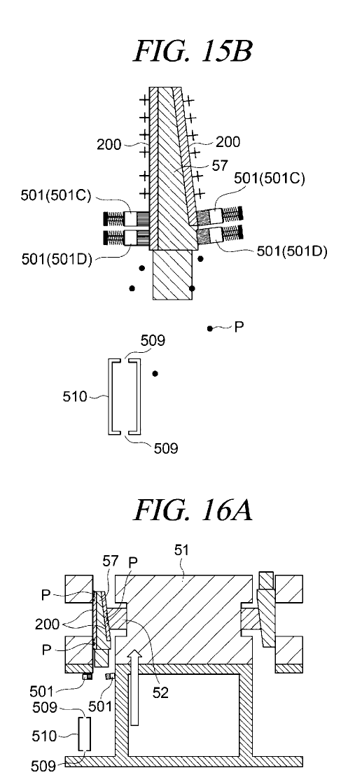

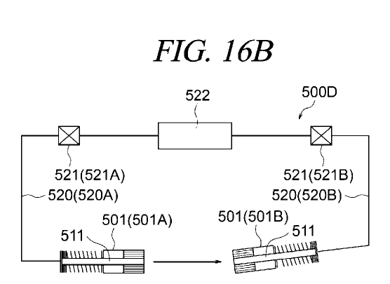

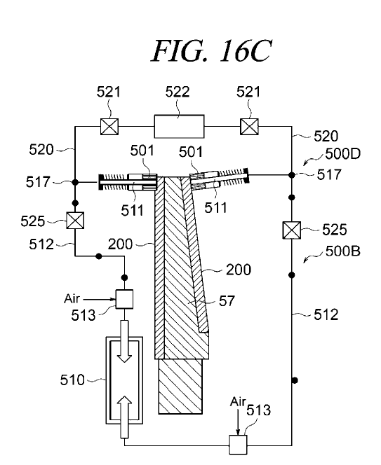

Now, a lock key cleaning device 500D according to a fourth exemplary embodiment will be explained with reference to FIG. 16A to FIG. 16C. For simplicity of explanation, a case where a single pair of brushes 501 facing each other is provided for one lock key 57 will be explained. For convenience’ sake, one of the pair of brushes 501 facing each other will be referred to as a first brush 501A, and the other as a second brush 501B.

In this fourth exemplary embodiment, as shown in FIG. 16B, a brush having the same air passage 511 as the brush 501 of the second exemplary embodiment is employed. The air passage 511 of the first brush 501A (501) is connected to a pressurized gas source 522 via a gas supply line 520A (520) that is provided with an opening/closing valve 521A (521). The air passage 511 of the second brush 501B (501) is connected to the pressurized gas source 522 via a gas supply line 520B (520) that is provided with an opening/closing valve 521B (521). The pressurized gas source 522 is provided as a plant utility, for example, and may supply clean air (or a nitrogen gas) as a pressurized gas.

As shown in FIG. 16A, when the lock key 57 is placed at the lock position, the opening/closing valve 521A is opened and the opening/closing valve 521B is closed, and the gas is jetted from the first brush 501A to the second brush 501B, as illustrated in FIG. 16B. Subsequently, the opening/closing valve 521A is closed and the opening/closing valve 521B is opened, and the gas is jetted from the second brush 501B to the first brush 501A. This operation is then repeated one or more times, desirably multiple times. As a result, the wear particles adhering to the brush 501 are blown off. The blown-away, floating wear particles are then sucked in and collected by the local exhaust duct 510, which has an opening. With this configuration, the wear particles attached to the brush 501 (501A and 501B) can be suppressed from re-adhering to the lock key 57, so that the cleaning efficiency of the lock key 57 can be improved.

As shown in FIG. 16C, the air passage 511 of the brush 501 (501A, 501B) may be used as both a suction path and a discharge path. The configuration shown in FIG. 16C is conceived by combining the configuration shown in FIG. 14 and the configuration shown in FIG. 16B, in which a valve (opening/closing valves 525 and 521) for switching between suction and discharge is provided. That is, a connection point 517 is provided on the suction line (gas line) 512 between the brush 501 and the ejector 513, and the gas supply line 520 equipped with the opening/closing valve 521, as shown in FIG. 16B, is connected to this connection point 517. Furthermore, the opening/closing valve 525 is provided slightly downstream of the connection point 517 on the suction line 512. Instead of providing the opening/closing valves 521 and 525, a three-way valve may be provided at the position of the connection point 517.

By opening the opening/closing valve 521 and closing the opening/closing valve 525, the air passage 511 of the brush 501 can be used as the gas jetting path. By closing the opening/closing valve 521 and opening the opening/closing valve 525, the air passage 511 of the brush 501 can be used as the suction path.

While jetting a gas from one of the pair of brushes 501 facing each other, suction may be performed by the other brush. That is, the gas may be jetted from the first brush 501A (501) while the suction is performed by the second brush 501B, and thereafter, the gas may be jetted from the second brush 501B (501) while the suction is performed by the first brush 501A. In this case, some of the wear particles blown off from one of the brushes can be collected through the air passage 511 of the other brush.

The configuration of the fourth exemplary embodiment described above can also be applied to a configuration in which a pair of charging brushes 501C (501) and a pair of static elimination brushes 501D (501) are provided for the single lock key 57, as in the third exemplary embodiment. In this case, it is desirable to first eject the gas from all (two) brushes on the same side (e.g., the front side) of the lock key 57, and then eject the gas from all (two) brushes on the other side (e.g., the rear side) of the lock key 57, in order to suppress a decrease in a gas flow velocity due to interference between the ejected gas streams.

The above exemplary embodiments have been described for the case where the resin layer 200 is provided on the surface of the lock key 57 and the wear particles are thus resin wear particles, but the exemplary embodiments are not limited thereto. The lock key 57 may not have the resin layer 200 on the surface thereof. In this case, metal wear particles may be generated, but the lock key 57 with these metal wear particles attached thereto can also be cleaned by the lock key cleaning device with the brush described above (however, the function of facilitating the removal of the wear particles using the charging of the resin cannot be used). Wear particles may also be generated from the rolling bodies 60 (balls or rollers), but the amount is negligible and can be removed with the brush.

Although the above description has been made only for the cleaning of the lock key 57 on the first opening Sa side, a cover and a lock key are also provided on the second opening Sb side, (see members denoted by reference numerals 52' and 57' in FIG. 12A). During a normal operation, the cover body on the second opening Sb side is always kept closed, and the lock key on the second opening Sb side is always kept at the lock position. When the pressure in the drying chamber S rises, the wear particles are generated by the sliding movement between the cover body and the lock key on the second opening Sb side due to the mechanism described above. While this wear particles are hardly likely to have an adverse effect on the substrate W, a lock key cleaning device may be additionally provided to clean the lock key on the second opening Sb side. Since the second opening Sb is opened during the maintenance, for example, cleaning the lock key before the maintenance may facilitate the maintenance work.

It should be noted that the above-described exemplary embodiments are illustrative in all aspects and are not anyway limiting. The above-described exemplary embodiments may be omitted, replaced and modified in various ways without departing from the scope and the spirit of claims.

In each of the above-described exemplary embodiments, cleaning may be performed when every single substrate W is processed. Alternatively, cleaning may be performed periodically when a processing of the first substrate W in a processing lot is begun, or whenever a preset number of substrates W has been processed, for example. In this case, a brush moving mechanism (not shown) configured to move the brush 501 back and forth with respect to the lock key 57 may be provided, and the brush 501 may be brought into contact with the lock key 57, which is moved up and down, only when cleaning is required.

According to the exemplary embodiment, it is possible to suppress the substrate from being contaminated with the particles from the lock key and the members in contact with it.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

We claim:

1. A substrate processing apparatus configured to dry a substrate by replacing a liquid film formed on a top surface of the substrate with a supercritical fluid, the substrate processing apparatus comprising:
a pressure vessel having therein a drying chamber in which the substrate is dried;
a cover body configured to close an opening of the drying chamber;
a lock key configured to restrict the cover body from moving from a closing position where the cover body closes the opening toward an opening position where the cover body opens the opening; and
a cleaning device configured to clean the lock key.

2. The substrate processing apparatus of claim 1, further comprising:
an elevating mechanism configured to move the lock key up and down between a lock position where the lock key restricts the cover body from moving from the closing position where the cover body closes the opening toward the opening position where the cover body opens the opening, and a lock release position where the lock key allows the cover body to move between the closing position and the opening position,
wherein the cleaning device cleans the lock key while the lock key is being moved by the elevating mechanism.

3. The substrate processing apparatus of claim 2,
wherein the cleaning device comprises a brush, and the lock key is cleaned by being rubbed by the brush while the lock key is being moved by the elevating mechanism.

4. The substrate processing apparatus of claim 3,
wherein the brush is spring-biased so as to be pressed against the lock key.

5. The substrate processing apparatus of claim 3, further comprising:
a suction device configured to suction particles rubbed off the lock key by the brush.

6. The substrate processing apparatus of claim 5,
wherein the suction device has a suction opening provided in the brush.

7. The substrate processing apparatus of claim 5,
wherein the suction device has a suction opening provided below the brush, and the suction opening sucks in the particles floating below the brush.

8. The substrate processing apparatus of claim 3,
wherein the brush includes a first brush and a second brush, and the first brush is configured to be brought into contact with a first surface of the lock key that comes into contact with the cover body, while the second brush is configured to be brought into contact with a second surface of the lock key opposite to the first surface.

9. The substrate processing apparatus of claim 3,
wherein a resin layer is provided on a surface of the lock key that receives a load applied from the cover body when the lock key is located at the lock position.

10. The substrate processing apparatus of claim 9,
wherein the brush includes a first brush and a second brush, and the first brush is made of a material that charges the resin layer when rubbed against the resin layer, while the second brush is made of a material that eliminates static electricity of the resin layer when rubbed against the resin layer.

11. The substrate processing apparatus of claim 10,
wherein the first brush is disposed above the second brush.

12. The substrate processing apparatus of claim 3, further comprising:
a gas ejector configured to eject a gas toward the brush to blow off particles adhering to the brush.

13. The substrate processing apparatus of claim 8,
wherein the first brush is provided with a first gas ejector configured to eject a gas toward the second brush to blow off particles adhering to the second brush, and the second brush is provided with a second gas ejector configured to eject a gas toward the first brush to blow off particles adhering to the first brush.

14. A cleaning method of cleaning a lock key in a substrate processing apparatus including a pressure vessel having therein a drying chamber in which a substrate is dried by replacing a liquid film formed on a top surface of the substrate with a supercritical fluid, a cover body configured to close an opening of the drying chamber, and the lock key that restricts a movement of the cover body, the lock key being configured to be moved up and down between a lock position where the lock key restricts the cover body from moving from a closing position where the cover body closes the opening toward an opening position where the cover body opens the opening, and a lock release position where the lock key allows the cover body to move between the closing position and the opening position, the cleaning method comprising:
preparing a brush at a position where the brush comes into contact with the lock key when the lock key is moved between the lock position and the lock release position; and
removing particles adhering to a surface of the lock key from the lock key by moving the lock key between the lock position and the lock release position to rub the lock key with the brush.

15. The cleaning method of claim 14, further comprising:
collecting the particles rubbed off the lock key by the brush.

16. The cleaning method of claim 14,
wherein a resin layer is provided on the surface of the lock key,
the brush is made of a material that charges the resin layer when rubbed against the resin layer, and
the cleaning method further comprises:
charging the resin layer with the brush when the lock key is moved from the lock release position to the lock position;
causing the particles adhering to the cover body to adhere to the resin layer of the lock key by an electrostatic attracting force by bringing the charged resin layer into contact with the cover body; and
removing the particles adhering to the resin layer of the lock key by the brush when the lock key is moved from the lock position to the lock release position.

17. The cleaning method of claim 14,
wherein the cleaning of the lock key is performed either before a first substrate of a processing lot is processed, or whenever a preset number of substrates has been processed.
